(19) United States
(12) Patent Application Publication
(10) Pub. No.: US 2003/0234344 A1
(43) Pub. Date: Dec. 25, 2003

(54) Logarithmic mode CMOS image sensor with reduced in-pixel fixed

(76) Inventors: Liang-Wei Lai, Banchiau City (TW); Ya-Chin King, Chungli (TW)

Correspondence Address: J.C. Patents, Inc., Suite 250, 4 Venture, Irvine, CA, 92618, US

(21) Appl. No.: 10/217,196

(22) Filed: Aug. 8, 2002

(30) Foreign Application Priority Data
Jun. 20, 2002 (TW) 91113451

(51) Int. Cl. H01L 27/00

(52) U.S. Cl. 250/208.1

(57) ABSTRACT

A logarithmic mode CMOS image sensor capable of eliminating in-pixel fixed pattern noise. The image sensor includes a first MOS transistor, a second MOS transistor, a third MOS transistor, a fourth MOS transistor, a photodiode and a current source. The gate terminal of the first MOS transistor and the first connection terminal are tied at a first node point. The first node point is connected to a terminal with the highest voltage in the circuit. The gate terminal of the second MOS transistor and the second connection terminal of the first MOS transistor are tied at a second node point. The first connection terminal of the second MOS transistor is also connected to the terminal with the highest voltage. The gate terminal of the third MOS transistor is tied to a row select signal terminal and the first connection terminal of the third MOS transistor is tied to the second terminal of the second MOS transistor. The second connection terminal of the third MOS transistor is a voltage output terminal. The gate terminal of the fourth MOS transistor is tied to a control signal terminal and the first connection terminal of the fourth MOS transistor is tied to the second node point. The first connection terminal of the photodiode is tied to the second connection terminal of the fourth MOS transistor and the second connection terminal of the photodiode is tied to a ground terminal. The first connection terminal of the current source is tied to the second connection terminal of the third MOS transistor and the second connection terminal of the current source is tied to a ground terminal.

### CROSS-REFERENCE TO RELATED APPLICATION

This application claims the priority benefit of Taiwan application Ser. No. 91113451, filed Jun. 20, 2002

### BACKGROUND OF THE INVENTION

1. Field of Invention

The present invention relates to a logarithmic mode CMOS image sensor. More particularly, the present invention relates to a logarithmic mode CMOS image sensor with reduced in-pixel fixed pattern noise.

2. Description of Related Art

An ideal image sensor should have a high dynamic range (for increasing the range of illumination), a low dark current (applicable in a dim environment) and low power consumption. Furthermore, image data must be able to be captured quickly and randomly accessed. At present, the most commonly used image sensor is the charge-coupled device (CCD). Although most CCD devices generally have a high dynamic range and a low dark current, special processes demanded for manufacturing the CCD device result in very expensive. Moreover, circuits inside the CCD require a high driving voltage supply. Hence, considerable power is consumed by each CCD cell.

Relatively speaking, a CMOS image sensor has properties including high quantum efficiency, low read-out noise, high dynamic range and random access capacity. Moreover, a CMOS image sensor is a hundred percent compatible with other CMOS fabrication process. In other words, a CMOS image sensor has none of the drawbacks of a charge-coupled device. Furthermore, rapid progress in the technique for fabricating CMOS devices also has reduced the production cost of a CMOS sensor considerably. Improved manufacturing methods have also reduced pixel size and overall power consumption. Consequently, many low-end imaging products use CMOS image sensors instead of the CCD device.

A logarithmic mode CMOS image sensor is one type of CMOS image sensor. FIG. 1 is a simplified circuit diagram of a conventional logarithmic mode CMOS image sensor. As shown in FIG. 1, a logarithmic mode CMOS image sensor mainly includes three NMOS transistors 101, 103, 105 and a photodiode 107. The gate of the transistor 101 is tied to the high voltage Vdd. The voltage between the gate terminal and the source terminal of the transistor 101 response to the drain current in a logarithmic fashion. Hence, the output voltage Vₒᵤₜ and the photocurrent induced by the photodiode 107 have a logarithmic relationship. With this arrangement, the logarithmic mode CMOS image sensor has a very high dynamic range. In addition, image contrast is very strong. However, the read-out voltage is often interfered by excessive in-pixel fixed patterned noise due to a threshold voltage variation of MOS transistor resulting from fabrication. Moreover, correlated double sampling (CDS) technique cannot be applied to eliminate fixed pattern noise in a logarithmic mode CMOS image sensor.

### SUMMARY OF THE INVENTION

Accordingly, one object of the present invention is to provide a logarithmic mode CMOS image sensor capable of eliminating in-pixel fixed pattern noise inside the logarithmic mode CMOS image sensor through correlated double sampling (CDS) technique. Ultimately, quality of captured images is improved.

To achieve these and other advantages and in accordance with the purpose of the invention, as embodied and broadly described herein, the invention provides a logarithmic mode CMOS image sensor capable of eliminating in-pixel fixed pattern noise. The image sensor includes a first MOS transistor, a second MOS transistor, a third MOS transistor, a fourth MOS transistor, a photodiode and a current source. The first MOS transistor has a gate terminal, a first connection terminal and a second connection terminal. The gate terminal of the first MOS transistor and the first connection terminal are tied at a first node point. The first node point is connected to a terminal with a high voltage, such as the highest voltage, in the circuit. The second MOS transistor has a gate terminal, a first connection terminal and a second connection terminal. The gate terminal of the second MOS transistor and the second connection terminal of the first MOS transistor are tied at a second node point. The first connection terminal of the second MOS transistor is also connected to the terminal with the highest voltage. The third MOS transistor has a gate terminal, a first connection terminal and a second connection terminal. The gate terminal of the third MOS transistor is tied to a row select signal terminal and the first connection terminal of the third MOS transistor is tied to the second terminal of the second MOS transistor. The second connection terminal of the third MOS transistor is a voltage output terminal. The fourth MOS transistor has a gate terminal, a first connection terminal and a second connection terminal. The gate terminal of the fourth MOS transistor is tied to a control signal terminal and the first connection terminal of the fourth MOS transistor is tied to the second node point. The photodiode has a first connection terminal and a second connection terminal. The first connection terminal of the photodiode is tied to the second connection terminal of the fourth MOS transistor and the second connection terminal of the photodiode is tied to a ground terminal.

In the preferred embodiment of this invention, the first MOS transistor, the second MOS transistor, the third MOS transistor and the fourth MOS transistor are N-channel MOS transistors. Note that the fourth MOS transistor can be a P-channel MOS transistor.

This invention also provides a method of operating a logarithmic mode CMOS image sensor with minimal in-pixel fixed pattern noise. First, the logarithmic mode CMOS image sensor initiates a signal voltage sampling when the fourth MOS transistor receives an enable signal through the control terminal. Secondly, the logarithmic mode CMOS image sensor initiates load voltage sampling when the fourth MOS transistor receives a disable signal through the control terminal. Next, using CDS circuit to subtract the two signals. A final signal is the obtained.

In brief, adding one more MOS transistor to a conventional logarithmic mode CMOS image sensor circuit can eliminate most part of in-pixel fixed pattern noise.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a simplified circuit diagram of a conventional logarithmic mode CMOS image sensor,

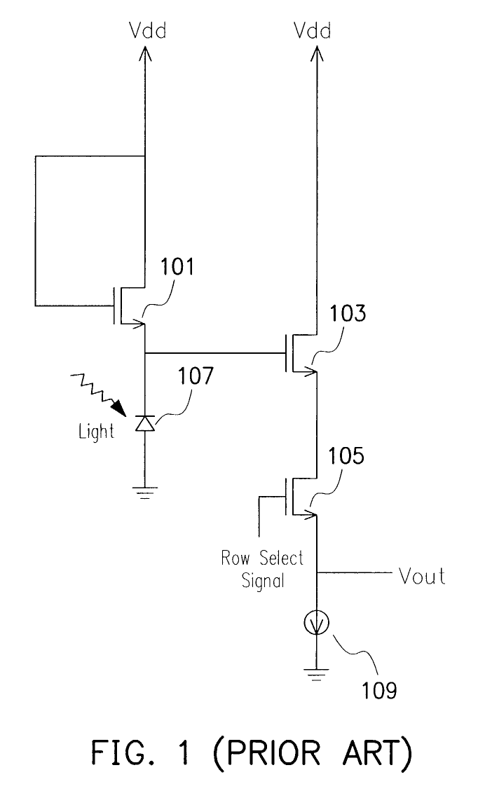

FIG. 2 is a simplified circuit diagram of a logarithmic mode CMOS image sensor for eliminating in-pixel fixed pattern noise according to one preferred embodiment of this invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

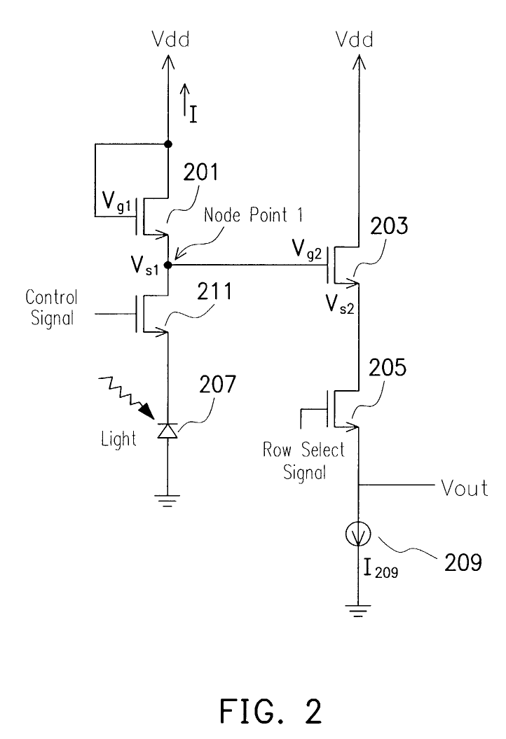

FIG. 2 is a simplified circuit diagram of a logarithmic mode CMOS image sensor for eliminating in-pixel fixed pattern noise according to one preferred embodiment of this invention. As shown in FIG. 2, the logarithmic mode CMOS image sensor comprises four NMOS transistors 201, 203, 205, 211, a photodiode 207 and a current source 209.

The following is a description of the operating principles of the logarithmic mode CMOS image sensor. A few definitions are defined as follows: V_{g201} represents the voltage at the gate terminal of the NMOS transistor 201, Vₛ₂₀₁ represents the voltage at the source terminal of the NMOS transistor, Vₜₕ₂₀₁ represents the threshold voltage of the NMOS transistor 201 and so on, and I₂₀₉ represents current provided by the current source 209.

According to the drain current formula for an NMOS transistor operating in a sub-threshold region, the current I flowing through the NMOS transistor is given by:

$$I = {I}_{0} \cdot Exp [ \frac{{V}_{g201} - {V}_{s201} - {V}_{th201}}{{nV}_{T}} ] \qquad ( 1 )$$

where I₀ is the leakage current flowing through the NMOS transistor 201 when V_{g201}−Vₛ₂₀₁=0V and V_{T} is the thermal voltage (equivalent to KT/q). From equation (1),

$$n {V}_{T} ln [ \frac{I}{{I}_{0}} ] = {V}_{g201} - {V}_{s201} - {V}_{th201} \cdot In other words , {V}_{s201} = {V}_{g201} - {V}_{th201} - n {V}_{T} ln [ \frac{I}{{I}_{0}} ] .$$

Since

V_{g201} is almost equivalent to a high voltage, such as the highest voltage, in the circuit V_{dd}, hence

$${V}_{s201} = {V}_{dd} - {V}_{th201} - n {V}_{T} ln [ \frac{I}{{I}_{0}} ] \qquad ( 2 )$$

Since the NMOS transistor 203 operates in the saturated region, drain current flowing through the NMOS transistor 203 will almost equal the current I₂₀₉ provided by the current source 209. Thus, the current I₂₀₉ is almost equal to the source current of the NMOS transistor 203. According to the source current formula for an NMOS transistor operating in the saturated region, source current through the NMOS transistor 203 is ½ K_{P203}(V_{g203}−Vₛ₂₀₃−Vₜₕ₂₀₃)², which is equal to I₂₀₉. In other words,

$${I}_{209} = \frac{1}{2} {{K}_{P203} ( {V}_{g203} - {V}_{s203} - {V}_{th203} )}^{2} .$$

By deduction,

$$\sqrt{\frac{2 {I}_{209}}{{K}_{P203}}} = {V}_{g203} - {V}_{s203} - {V}_{th203} .$$

Under an ideal condition, Vₛ₂₀₃ is equivalent to the output voltage Vₒᵤₜ from the logarithmic mode CMOS image sensor. Hence,

$${V}_{out} = {V}_{s203} = {V}_{g203} - {V}_{th203} - \sqrt{\frac{2 {I}_{209}}{{K}_{P203}}} \qquad ( 3 )$$

where K_{P203} is a device parameter for the NMOS transistor 203. Since Vₛ₂₀₁=V_{g203}, substituting equation (2) into equation (3) gives:

$${V}_{out} = {V}_{dd} - {V}_{th201} - n {V}_{T} ln [ \frac{I}{{I}_{0}} ] - {V}_{th203} - \sqrt{\frac{2 {I}_{209}}{{K}_{P203}}} \qquad ( 4 )$$

When the photodiode 207 picks up weak illumination (the NMOS transistor 201 operates in the sub-threshold region) and the NMOS transistor 211 receives an ‘OFF’ control signal, a current I, that is, a reverse bias current Iᵣₑᵥ₁ flows into the node point 1. Hence, the output voltage Vₒᵤₜ₁₁ or the load voltage during correlated double sampling (CDS) of the logarithmic mode CMOS image sensor is given by the formula:

$${V}_{out11} = {V}_{dd} - {V}_{th201} - n {V}_{T} ln [ \frac{{I}_{rev1}}{{I}_{0}} ] - {V}_{th203} - \sqrt{\frac{2 {I}_{209}}{{K}_{P203}}} \qquad ( 5 )$$

When the photodiode 207 picks up weak illumination and the NMOS transistor 211 receives an ‘ON’ control signal, a current I, equivalent to the photocurrent I_{P1} generated by the illuminated photodiode 207 and the reverse bias current Iᵣₑᵥ₁ to the node point 1 (leakage current from the photodiode without illumination). Hence, the output voltage Vₒᵤₜ₁₂ or the signal voltage during correlated double sampling (CDS) of the logarithmic mode CMOS image sensor is given by the formula:

$${V}_{out12} = {V}_{dd} - {V}_{th201} - n {V}_{T} ln [ \frac{{I}_{P1} + {I}_{rev1}}{{I}_{0}} ] - {V}_{th203} - \sqrt{\frac{2 {I}_{209}}{{K}_{P203}}} \qquad ( 6 )$$

Therefore, when the photodiode 207 picks up weak illumination while the NMOS transistor 211 receives either an enable or a disable control signal to sample load voltage Vₒᵤₜ₁₁ and signal voltage Vₒᵤₜ₁₂ through the CDS circuit, a pure signal voltage is obtained by subtraction, that is:

$$\vert {V}_{out12} - {V}_{out11} \vert = n {V}_{T} ln [ \frac{{I}_{P1} + {I}_{rev1}}{{I}_{rev1}} ] \qquad ( 7 )$$

Similarly, when the photodiode 207 picks up highillumination (the NMOS transistor 201 operates in the saturation region) and the NMOS transistor 211 receives an ‘OFF’ control signal, a current I, that is, a reverse bias current Iᵣₑᵥ₁ flows into the node point 1. Hence, the output voltage Vₒᵤₜ₂₁ of the logarithmic mode CMOS image sensor is given by the formula:

$${V}_{out 21} = {V}_{dd} - {V}_{th201} - n {V}_{T} ln [ \frac{{I}_{rev1}}{{I}_{o}} ] - {V}_{th203} - \sqrt{\frac{2 {I}_{209}}{{K}_{P203}}} \qquad ( 8 )$$

When the photodiode 207 picks up high illumination and the NMOS transistor 211 receives an ‘ON’ control signal, a current I, the output voltage Vₒᵤₜ₂₂ of the logarithmic mode CMOS image sensor is given by the formula:

$${V}_{out 22} = {V}_{dd} - {V}_{th201} - \sqrt{\frac{2 ( {I}_{P1} + {I}_{rev1} )}{{K}_{P201}}} - {V}_{th203} - \sqrt{\frac{2 {I}_{209}}{{K}_{P203}}} \qquad ( 9 )$$

Therefore, when the photodiode 207 picks up highillumination while the NMOS transistor 211 receives either an enable or a disable control signal to match the CDS circuit for reset voltage Vₒᵤₜ₁₁ and signal voltage Vₒᵤₜ₁₂ sampling, a pure signal voltage is obtained after subtraction, that is:

$$\vert {V}_{out 22} - {V}_{out 21} \vert = \sqrt{\frac{2 ( {I}_{P1} + {I}_{rev1} )}{{I}_{o}}} - n {V}_{T} ln [ \frac{{I}_{rev1}}{{I}_{o}} ] \qquad ( 10 )$$

According to equations (7) and (10), fixed pattern noise due to threshold voltage variation is canceled. Hence, the output voltage Vₒᵤₜ of the logarithmic mode CMOS image sensor responds to the photocurrent generated by the photodiode 207 under illumination in a logarithmic fashion. By controlling the row select signal, signals are transmitted from the NMOS transistor to a correlated sampling circuit for sampling. After the sampled signal voltage Vₒᵤₜ₁₂, Vₒᵤₜ₂₂ and load voltage Vₒᵤₜ₁₁, Vₒᵤₜ₂₁ are subtracted, any mismatch between the threshold voltage of various transistors inside the logarithmic mode CMOS image sensor array are canceled out so that quality of output voltage is improved.

Note that the highest voltage V_{dd} is selected according to the manufacturing technique used in fabricating the logarithmic mode CMOS image sensor. For example, if the line width of the fabrication process is 0.25 μm, the highest voltage V_{dd} is about 2.5V. If the line width is 0.35 μm, the highest voltage V_{dd} is about 3.3V. If the line width is 0.5 μm, the highest voltage V_{dd} is 5V.

In summary, by adding one more MOS transistor, when the logarithmic mode CMOS image sensor circuit is performing thecorrelated double sampling, the threshold voltage variation produced in the pixel and most part of in-pixel fixed pattern noise can be effectively eliminated while the output voltage is exported. Hence, output voltage is stabilized and image quality is improved.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A logarithmic mode CMOS image sensor with reduced in-pixel fixed pattern noise, comprising:
a first MOS transistor having a gate terminal, a first connection terminal and a second connection terminal, wherein the gate terminal and the first connection terminal of the first MOS transistor are tied to a first node point and the first node point is tied to a terminal for receiving a high voltage Vdd in the circuit;
a second MOS transistor having a gate terminal, a first connection terminal and a second connection terminal, wherein the gate terminal of the second MOS transistor and the second connection terminal of the first MOS transistor are tied to a second node point and the first connection terminal of the second MOS transistor is tied to the terminal for receiving the highest voltage in the circuit;
a third MOS transistor having a gate terminal, a first connection terminal and a second connection terminal, wherein the gate terminal of the third MOS transistor is tied to a terminal for receiving a row select signal, the first connection terminal of the third MOS transistor is tied to the second connection terminal of the second MOS transistor and the second connection terminal of the third MOS transistor is a voltage output terminal;
a fourth MOS transistor having a gate terminal, a first connection terminal and a second connection terminal, wherein the gate terminal of the fourth MOS transistor is tied to a control signal terminal and the first connection terminal of the fourth MOS transistor is tied to the second node point; and
a photodiode with a first connection terminal and a second connection terminal, wherein the first connection terminal of the photodiode is tied to the second connection terminal of the fourth MOS transistor and the second connection terminal of the photodiode is tied to a ground terminal.

2. The CMOS image sensor of claim 1, wherein sensor further includes:
a current source with a first connection terminal and a second connection terminal, wherein the first connection terminal of the current source is tied to the second connection terminal of the third MOS transistor and the second connection terminal of the current source is tied to a ground terminal.

3. The CMOS image sensor of claim 1, wherein the first MOS transistor, the second MOS transistor, the third MOS transistor and the fourth MOS transistor are N-channel MOS transistors.

4. The CMOS image sensor of claim 1, wherein the first MOS transistor, the second MOS transistor, the third MOS transistor and the fourth MOS transistor are P-channel MOS transistors.

5. The CMOS image sensor of claim 1, wherein the voltage at the second connection terminal of the second MOS transistor and the voltage at the voltage output terminal are identical under an ideal condition.

6. The CMOS image sensor of claim 3, wherein the highest voltage is between 5V and the threshold voltage of the N-channel MOS transistor.

7. A method of operating a logarithmic mode CMOS image sensor with a reduced in-pixel fixed pattern noise, wherein the logarithmic CMOS image sensor includes a first MOS transistor, a second MOS transistor, a third MOS transistor, a fourth MOS transistor, a photodiode and a current source, the first MOS transistor has a gate terminal, a first connection terminal and a second connection terminal, the gate terminal and the first connection terminal of the first MOS transistor are tied to a first node point and the first node point is tied to a terminal for receiving the highest voltage in the circuit; the second MOS transistor has a gate terminal, a first connection terminal and a second connection terminal, the gate terminal of the second MOS transistor and the second connection terminal of the first MOS transistor are tied to a second node point and the first connection terminal of the second MOS transistor is tied to the terminal for receiving the highest voltage in the circuit; the third MOS transistor has a gate terminal, a first connection terminal and a second connection terminal, the gate terminal of the third MOS transistor is tied to a terminal for receiving a row select signal, the first connection terminal of the third MOS transistor is tied to the second connection terminal of the second MOS transistor and the second connection terminal of the third MOS transistor is a voltage output terminal; the fourth MOS transistor has a gate terminal, a first connection terminal and a second connection terminal, the gate terminal of the fourth MOS transistor is tied to a control signal terminal and the first connection terminal of the fourth MOS transistor is tied to the second node point; the photodiode has a first connection terminal and a second connection terminal, the first connection terminal of the photodiode is tied to the second connection terminal of the fourth MOS transistor and the second connection terminal of the photodiode is tied to a ground terminal; the current source has a first connection terminal and a second connection terminal, the first connection terminal of the current source is tied to the second connection terminal of the third MOS transistor and the second connection terminal of the current source is tied to a ground terminal, the method comprising the steps of:
receiving a control signal to enable the fourth MOS transistor so that the logarithmic mode CMOS image sensor conducts a signal voltage sampling; and
receiving a control signal to disable the fourth MOS transistor so that the logarithmic mode CMOS image sensor conducts a load voltage sampling.

8. The operating method of claim 7, wherein the signal voltage is the voltage at the voltage output terminal of the fourth MOS transistor when the fourth MOS transistor is enabled, and the load voltage is the voltage at the voltage output terminal of the fourth MOS transistor when the fourth MOS transistor is disabled.

9. The operating method of claim 7, wherein the voltage at the second connection terminal of the second MOS transistor and the voltage at the voltage output terminal are identical when the logarithmic mode CMOS image sensor undergoes signal and load voltage sampling.

10. The operating method of claim 7, wherein the highest voltage is between 5V and the threshold voltage of the N-channel MOS transistor when the logarithmic mode CMOS image sensor undergoes signal and load voltage sampling.
